(19) United States
(12) Patent Application Publication
(10) Pub. No.: US 2017/0107611 A1
(43) Pub. Date: Apr. 20, 2017

(54) EVAPORATION DEVICE AND METHOD

(71) Applicant: BOE TECHNOLOGY GROUP CO., LTD., Beijing (CN)

(72) Inventors: Xindi ZHANG, Beijing (CN); Junmin SUN, Beijing (CN)

(73) Assignee: BOE TECHNOLOGY GROUP CO., LTD., Beijing (CN)

(21) Appl. No.: 15/221,044

(22) Filed: Jul. 27, 2016

(30) Foreign Application Priority Data
Oct. 15, 2015 (CN) 201510666908.0

(51) Int. Cl. C23C 14/56; C23C 14/24

(52) U.S. Cl. CPC C23C 14/568; C23C 14/243

(57) ABSTRACT

An evaporation device and an evaporation method are disclosed. The evaporation device includes: a coating chamber and a first evaporation source chamber, the coating chamber is provided with a substrate placement component, the first evaporation source chamber is provided with an evaporation source placement component, the evaporation source placement component is configured for placing an evaporation source; the coating chamber and the first evaporation source chamber are provided with a sealing component therebetween; the sealing component is configured to connect the coating chamber and the first evaporation source chamber upon being opened and to disconnect the coating chamber and the first evaporation source chamber upon being closed.

### TECHNICAL FIELD

The embodiments of the present disclosure relate to an evaporation device and an evaporation method.

### BACKGROUND

Evaporation refers to a process in which a film is formed on a work piece or a substrate after a material for forming the film is evaporated or sublimated and then deposited on the work piece or the substrate. Generally, in the process of evaporation, an evaporation device is required to create various environment conditions necessary for evaporation.

Generally, an evaporation device comprises a coating chamber. The coating chamber is provided with a heating component, an evaporation source (containing the material to form a film), and a substrate to be processed. Upon the evaporation device being used to form a film, the evaporation source and the substrate are placed in the coating chamber, then, the coating chamber is vacuumized, and next the evaporation source is heated by the heating component to coat a thin film on the substrate; and after the film coating process is finished, the coating chamber is open, and the substrate is taken out of the chamber.

Generally, after the evaporation device finishes a film coating process, it is necessary to open the coating chamber for replacing the substrate. At this time, the environment air may contact and contaminate the evaporation source.

### SUMMARY

A first aspect of the present disclosure provides an evaporation device. The evaporation device comprises: a coating chamber and a first evaporation source chamber, wherein the coating chamber is provided with a substrate placement component, the substrate placement component is configured for placing a substrate, the first evaporation source chamber is provided with an evaporation source placement component, the evaporation source placement component is configured for placing an evaporation source; and a sealing component provided between the coating chamber and the first evaporation source chamber, wherein the sealing component is configured to connect the coating chamber and the first evaporation source chamber upon being opened and to disconnect the coating chamber and the first evaporation source chamber upon being closed.

A second aspect of the present disclosure provides an evaporation method, which is used for the evaporation device, the evaporation device comprises a coating chamber and a first evaporation source chamber, the coating chamber is provided with a substrate placement component, the first evaporation source chamber is provided with an evaporation source placement component, and the coating chamber and the first evaporation source chamber are provided with a sealing component therebetween, and the method comprises: placing a substrate on the substrate placement component; placing a first evaporation source on the evaporation source placement component in the first evaporation source chamber; opening the sealing component between the coating chamber and the first evaporation source chamber; heating the first evaporation source to form a first film layer on the substrate; and closing the sealing component.

It should be understood that the general description above and the detailed description in the following are exemplary and illustrative, and thus are not limitative of the present disclosure.

### BRIEF DESCRIPTION OF THE DRAWINGS

In order to clearly illustrate the technical solutions of the embodiments of the present disclosure, the drawings of the embodiments will be briefly described in the following; it is obvious that the described drawings are only related to some embodiments of the disclosure and thus are not limitative of the present disclosure.

FIG. 1 is a structural schematic view of an evaporation device provided by an embodiment of the present disclosure;

FIG. 2-1 is a structural schematic view of another evaporation device provided by an embodiment of the present disclosure;

FIG. 2-2 is a structural schematic view of another evaporation device provided by an embodiment of the present disclosure;

FIG. 2-3 is an external structural schematic view of the evaporation device illustrated by FIG. 2-1;

FIG. 2-4 is a structural schematic view of another evaporation device provided by an embodiment of the present disclosure;

FIG. 3 is a flow diagram of an evaporation method provided by an embodiment of the present disclosure;

FIG. 4-1 is a flow diagram of another evaporation method provided by an embodiment of the present disclosure;

FIG. 4-2 is a schematic view upon moving an evaporation source placement component into a coating chamber in the embodiment illustrated by FIG. 4-1;

FIG. 4-3 is a flow diagram of forming a first film layer on a substrate in the embodiment illustrated by FIG. 4-1;

FIG. 5-1 is a flow diagram of another evaporation method provided by an embodiment of the present disclosure;

FIG. 5-2 is a schematic view upon moving an evaporation source placement component into a coating chamber in the embodiment illustrated by FIG. 5-1; and

FIG. 5-3 is a flow diagram of forming a first film layer on a substrate in the embodiment illustrated by FIG. 5-1.

### DETAILED DESCRIPTION

In order to make objects, technical solutions and advantages of the embodiments of the disclosure apparent, the technical solutions of the embodiment will be described in a clearly and fully understandable way in connection with the drawings related to the embodiments of the disclosure. It is obvious that the described embodiments are just a part but not all of the embodiments of the disclosure. Based on the described embodiments herein, those skilled in the art can obtain other embodiment(s), without any inventive work, which should be within the scope of the disclosure.

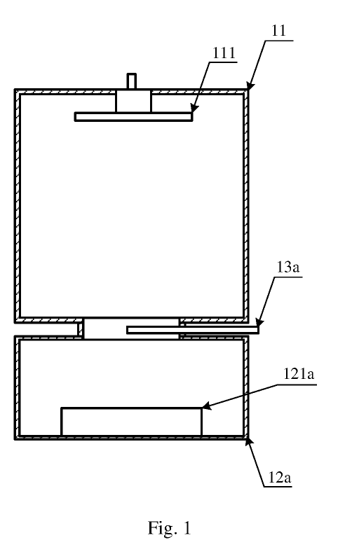

FIG. 1 is a structural schematic view of an evaporation device provided by an embodiment of the present disclosure. The evaporation device can comprise: a coating chamber 11 and at least one evaporation source chamber. A substrate placement component 111 is disposed in the coating chamber 11, and the substrate placement component 11 is configured for placing a substrate thereon. An evaporation source placement component 121a is disposed in a first evaporation source chamber 12a in the at least one evaporation source chamber. The evaporation source placement component 121a is configured for placing an evaporation source thereon. The first evaporation source chamber 12a can be any one of the at least evaporation source chamber for the purpose of description.

A sealing component 13a is provided between the coating chamber 11 and the first evaporation source chamber 12a. Upon the sealing component 13a being opened, the coating chamber 11 and the first evaporation source chamber 12a are connected. Upon the sealing component 13a being closed, the coating chamber 11 and the first evaporation source chamber 12a are disconnected.

The example illustrated by FIG. 1 only comprises one evaporation source chamber; however, those skilled in the technical art should understand that there can be a plurality of evaporation source chambers.

The evaporation device provided by an embodiment of the present disclosure can resolve the problem that the environment air may contact and contaminate an evaporation source when it is necessary to open the coating chamber for replacing a substrate in operation after an evaporation device in the related technology finishes a film coating process, and the evaporation device comprises at least one evaporation source chamber configured for placing the evaporation source and connects or disconnects the evaporation source chamber and a coating chamber through the sealing component disposed between the evaporation source chamber and the coating chamber, and achieves the effect of preventing the air contaminating the evaporation source when disconnecting the evaporation source chamber and the coating chamber by closing the sealing component after completion of film coating.

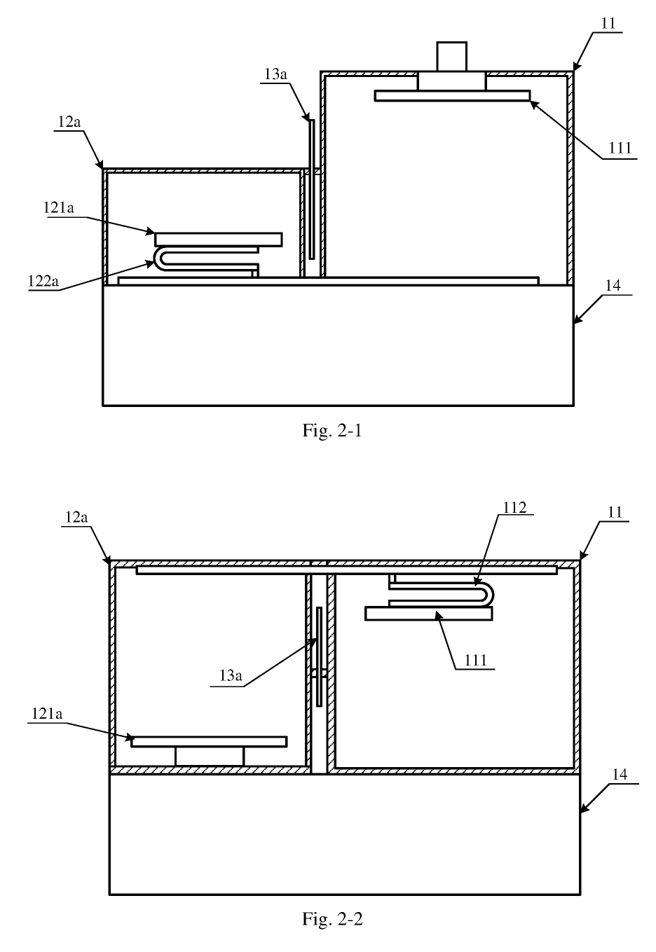

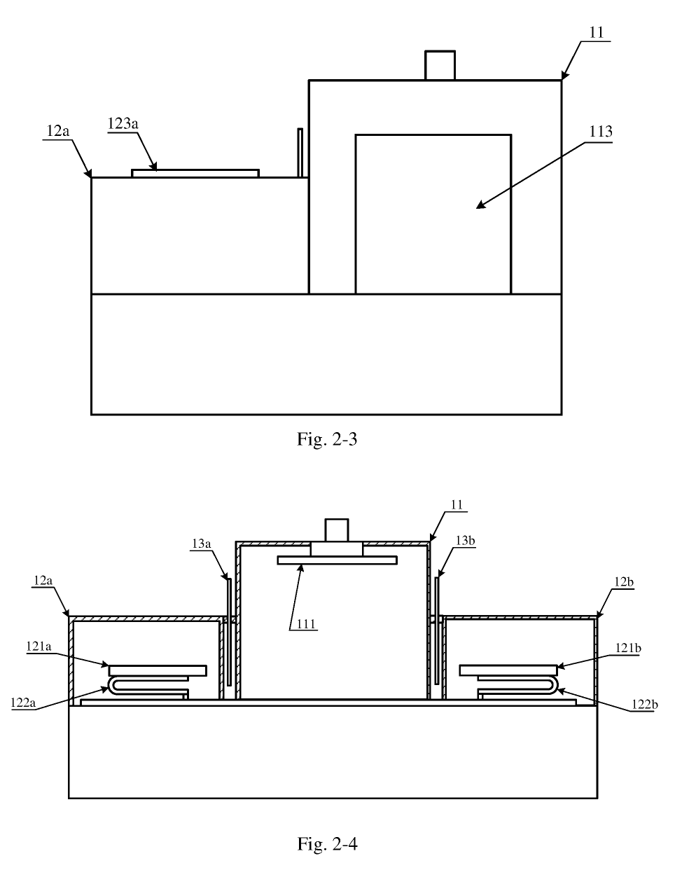

Furthermore, FIG. 2-1 illustrates a structural schematic view of another evaporation device provided by an embodiment of the present disclosure. The evaporation device is additionally provided with more components on the basis of the evaporation device illustrated by FIG. 1, in this way, the evaporation device provided by an embodiment of the present disclosure can have better performance and effect.

For example, the first evaporation source chamber 12a is further provided with an evaporation source moving component 122a. The evaporation source moving component 122a is connected with the evaporation source placement component 121a, and can drive the evaporation source placement component 121a to move into the coating chamber 11 upon the sealing component 13a being opened. The sealing component 13a may be a gate or valve. A sealing component is provided between the coating chamber 11 and each of the evaporation source chambers. The evaporation source moving component 122a can drive the evaporation source placement component to move through a track, a wheel, a chain or the like, the embodiments of the present disclosure are not limited thereto.

Moreover, the substrate placement component 111 can drive the substrate disposed on it to rotate. For example, the evaporation source placement component 121a is a platform, upon the evaporation source placement component 121a moving to a position under the substrate placement component 111, the substrate placement component 111 can rotate with respect to a line perpendicular to the upper surface of the platform, so as to improve the evenness of the film layer formed on the substrate.

It should be noted that, the evaporation source moving component 122a can be further provided with a temperature measure element (for example, a thermoelectric couple), a cooling water pipe, a power line and a heating element (for example, a tungsten filament). The temperature measure element is configured to measure the temperature of the evaporation source, the cooling water pipe is configured to provide water flow to balance the temperature of the evaporation source, and the power line is configured to provide electrical energy to the heating element. The evaporation source moving component 122a can allow the evaporation source to be maintained at a relatively constant temperature for evaporation through the temperature element, the cooling water pipe, the power line and the heating element. Optionally, a configuration platform 14 can be further provided under the coating chamber 11 and the first evaporation source chamber 12a. The configuration platform 14 can provide water source to the cooling water pipe and provide electrical energy to the power line in the evaporation source moving component 122a. Besides, the coating chamber 11 can be further provided with a component to heat the evaporation source, such as an electron beam gun or a laser.

FIG. 2-2 illustrates a structural schematic view of another evaporation device of an embodiment of the present disclosure.

For example, the coating chamber 11 is further provided with a substrate moving component 112. The substrate moving component 112 is connected with the substrate placement component 111, and can drive the substrate placement component 111 to move into the first evaporation source chamber 12a upon the sealing component 13a being opened. In the evaporation device illustrated by FIG. 2-2, the first evaporation source chamber 12a may be provided with an evaporation source moving component or not provided; the embodiments of the present disclosure are not limited thereto. It should be noted that the evaporation source placement component 121a can be a platform. Upon the substrate placement component 111 moves to a position above the evaporation source placement component 121a, the substrate placement component 111 can rotate with respect to a line perpendicular to the upper surface of the platform, so as to increase the evenness of the film layer formed on the substrate.

It should be noted that, the evaporation source placement component 121a can be used to heat the evaporation source, or the first evaporation source chamber 12a can be provided with other component(s) to heat the evaporation source, such as an electron beam gun or a laser.

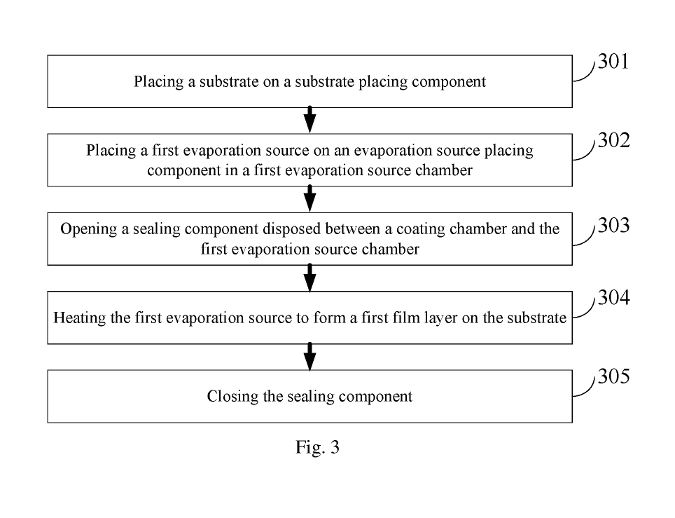

FIG. 2-3 illustrates an external structural schematic view of the evaporation device illustrated by FIG. 2-1. For example, the coating chamber 11 is provided with a first gate 113, the first gate 113 is configured to disconnect or connect the coating chamber 11 and the external environment. The first evaporation source chamber 12a is provided with a second gate 123a. The second gate 123a is configured to disconnect or connect the first evaporation source chamber 12a and external environmental. It should be noted that the first gate and the second gate can be provided at the other positions of the coating chamber and the first evaporation source chamber, and the embodiments of the present disclosure are not limited thereto.

For example, the number of evaporation source chambers may be at least two. For example, FIG. 2-4 illustrates a structural schematic view of another evaporation device provided by an embodiment of the present disclosure. In FIG. 2-4, there are two evaporation source chambers. The two evaporation source chambers can be the first evaporation source chamber 12a and the second evaporation source chamber 12b. The first evaporation source chamber 12a can be provided with an evaporation source placement component 121a and an evaporation source moving component 122a for the first evaporation source chamber. The first evaporation source chamber 12a and the coating chamber 11 are provided with a sealing component 13a therebetween. The second evaporation source chamber 12b can be provided with an evaporation source placement component 121b and an evaporation source moving component 122b for the second evaporation source chamber. The second evaporation source chamber 12b and the coating chamber 11 are provided with a sealing component 13b therebetween. The coating chamber 11 is provided with a substrate placement component 111 therein.

Two evaporation source chambers can operate to alternately provide an evaporation source to coat films on the substrate; besides, during one of the evaporation source chambers is under maintenance, the other one of the evaporation source chambers can be used to conduct film coating, which improves the operation efficiency of the evaporation device. For example, two evaporation source chambers can relatively quickly finish testing a huge numbers of evaporation source materials (during the test, it is necessary to use a huge number of evaporation source materials to coat films).

Moreover, the evaporation device can be provided with more evaporation source chambers, for example, three or four evaporation source chambers, and the embodiments of the present disclosure are not limited thereto.

It should be noted that the evaporation device provided by an embodiment of the present disclosure achieves the effect that the evaporation sources in two evaporation source chambers can be alternately used to coat films on the substrate without contacting the external air by disposing at least two evaporation source chambers, which reduces the times of evaporation source maintenance.

The evaporation device provided by an embodiment of the present disclosure can resolve the problem that the environment air may contact and contaminate an evaporation source when it is necessary to open the coating chamber for replacing a substrate in operation after the evaporation device in the related technology finishes a film coating process, and the evaporation device disposes at least one evaporation source chamber configured for placing the evaporation source and connects or disconnects the evaporation source chamber and a coating chamber through the sealing component disposed between the evaporation source chamber and the coating chamber, and achieves the effect of preventing environment air contaminating the evaporation source when disconnecting the evaporation source chamber and the coating chamber by closing the sealing component after completion of film coating.

FIG. 3 is a flow diagram of an evaporation method for an evaporation device provided by an embodiment of the present disclosure. The evaporation device can comprise: a coating chamber and at least one evaporation source chamber, the coating chamber is provided with a substrate placement component therein, the first evaporation source chamber is provided with an evaporation source placement component therein, the first evaporation source chamber can be any one of the at least one evaporation source chamber, and the coating chamber and the first evaporation source chamber are provided with a sealing component therebetween, the method comprises the following operations.

Step 301, placing a substrate on the substrate placement component;

Step 302, placing a first evaporation source on the evaporation source placement component in the first evaporation source chamber;

Step 303, opening the sealing component between the coating chamber and the first evaporation source chamber;

Step 304, heating the first evaporation source to form a first film layer on the substrate; and

Step 305, closing the sealing component.

To sum up, the evaporation method provided by an embodiment of the present disclosure can resolve the problem that the environment air may contact and contaminate an evaporation source when it is necessary to open the coating chamber for replacing a substrate in operation after an evaporation device in the related technology finishes a film coating process, and the evaporation method disposes at least one evaporation source chamber configured for placing the evaporation source and connects or disconnects the evaporation source chamber and a coating chamber through the sealing component disposed between the evaporation source chamber and the coating chamber, and achieves the effect of preventing the air contaminating the evaporation source when disconnecting the evaporation source chamber and the coating chamber by closing the sealing component after completion of film coating.

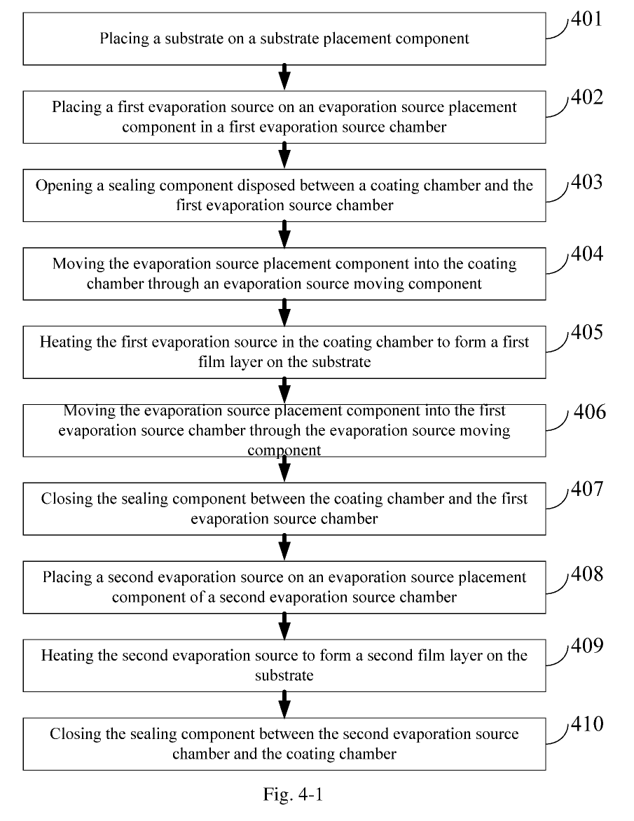

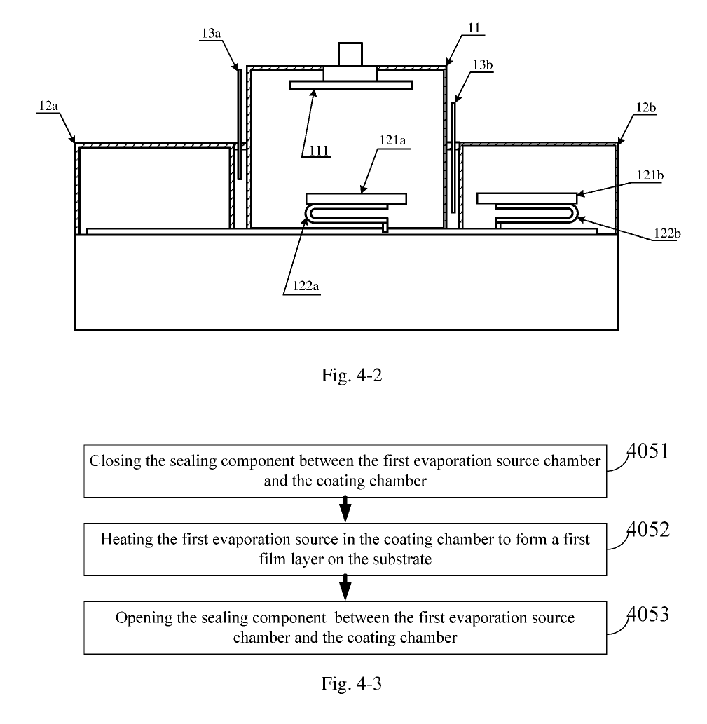

FIG. 4-1 is a flow diagram of another evaporation method for evaporation device provided by an embodiment of the present disclosure. The evaporation device can comprise: a coating chamber and at least one evaporation source chamber, the coating chamber is provided with a substrate placement component, the first evaporation source chamber is provided with an evaporation source placement component, the first evaporation source chamber can be any one of the at least one evaporation source chamber and the coating chamber and the first evaporation source chamber are provided with a sealing component therebetween, the method comprises the following operations.

Step 401, placing a substrate on the substrate placement component;

Step 402, placing a first evaporation source on the evaporation source placement component in the first evaporation source chamber;

Step 403, opening the sealing component between the coating chamber and the first evaporation source chamber;

Step 404, moving the evaporation source placement component into the coating chamber through the evaporation source moving component;

Step 405, heating the first evaporation source in the coating chamber to form a first film layer on the substrate;

Step 406, moving the evaporation source placement component into the first evaporation source chamber by the evaporation source moving component;

Step 407, closing the sealing component between the first evaporation source chamber and the coating chamber;

Step 408, placing a second evaporation source on the evaporation source placement component in the second evaporation source chamber;

Step 409, heating the second evaporation source to form a second film layer on the substrate; and

Step 410, closing the sealing component between the second evaporation source chamber and the coating chamber.

For example, in the present embodiment, in using the evaporation method provided by an embodiment of the present disclosure to conduct evaporation, in the step 401, a substrate can be disposed on the substrate placement component. The substrate is a work piece to be coated with a film thereon, and the purpose of the evaporation process is to form a film layer on the substrate. The substrate placement component can drive the substrate to rotate, so as to improve the evenness of the film layer formed on the substrate. Optionally, the coating chamber is provided with a first gate, and the substrate can be disposed on the substrate placement component by passing through the first gate.

In the step 402, a first evaporation source is disposed on the evaporation source placement component in the first evaporation source chamber.

The first evaporation source can be disposed on the evaporation source placement component in the first evaporation source chamber, while the evaporation source moving component can be provided with a temperature measure element (for example, a thermoelectric couple), a cooling water pipe, a power line and a heating element (for example, a tungsten filament). The temperature measure element is configured to measure the temperature of the evaporation source, the cooling water pipe is configured to provide water flow to balance the temperature of the evaporation source, and the power line is configured to provide electrical energy to the heating element. The evaporation source moving component can allow the evaporation source to be maintained in a relatively constant temperature for evaporation through the temperature element, the cooling water pipe, the power line and the heating element. The first evaporation source can be disposed on the evaporation source placement component by opening the second gate disposed on the first evaporation source chamber. The first evaporation source can be one or several kinds of materials to form films. After the second gate is opened to place the evaporation source, it is necessary to close the second gate to disconnect the external environment and the first evaporation source chamber.

It should be noted that the step 402 and the step 401 do not have a sequence limited therebetween, namely, the step 402 can be executed before the step 401, or the step 402 and the step 401 can be executed at the same time, the embodiments of the present disclosure are not limited thereto.

In the step 403, the sealing component between the coating chamber and the first evaporation source chamber is opened.

After the evaporation source and the substrate are placed, the sealing component between the coating chamber and the first evaporation source chamber can be opened. As illustrated by FIGS. 2-4, the sealing component 13a between the coating chamber 11 and the first evaporation source chamber 12a can be opened.

It should be noted that, if the sealing component between the coating chamber and the first evaporation source chamber has been in an open state, the present step can be omitted.

In step 404, the evaporation source placement component is moved into the coating chamber through the evaporation source moving component.

After opening of the sealing component between the coating chamber and the first evaporation source chamber, the evaporation source placement component can be moved into the coating chamber through the evaporation source moving component.

For example, FIG. 4-2 illustrates a schematic view upon moving the evaporation source placement component 121a into the coating chamber 11 through the evaporation source moving component 122 in the evaporation device illustrated by FIG. 2-4. The drawing reference numbers in FIG. 4-2 are in consistence with that in FIG. 2-4. The evaporation source placement component 121a can be moved to a position under the substrate placement component 111, so as to improve the quality of the film to be formed.

In the step 405, the first evaporation source is heated in the coating chamber to form a first film layer on the substrate.

After the evaporation source placement component is moved into the coating chamber, the first evaporation source can be heated in the coating chamber to form a first film layer. As illustrated by FIG. 4-3, the step 405 can comprise the following three sub-steps.

Sub-step 4051, closing the sealing component between the first evaporation source chamber and the coating chamber;

Sub-step 4052, heating the first evaporation source in the coating chamber to form a first film layer on the substrate; and

Sub-step 4053, opening the sealing component between the first evaporation source chamber and the coating chamber.

Sub-step 4051, closing the sealing component between the first evaporation source chamber and the coating chamber.

For example, after the evaporation source placement component is moved into the coating chamber, the sealing component between the first evaporation source chamber and the coating chamber can be closed. In this way, the problem can be avoided that the evaporated or sublimated substance may escape into the first evaporation source chamber after the evaporation source is evaporated or sublimated, and the escape may reduce the forming speed of the thin film on the substrate and waste the evaporation source.

It should be noted that, in the case where the evaporation device comprises a plurality of evaporation source chambers, the sealing components between all evaporation source chambers and the coating chamber can be closed or separately closed.

In the sub-step 4052, the first evaporation source is heated in the coating chamber to form a first film layer on the substrate. For example, in the present embodiment, after closing the sealing component between the first evaporation source chamber and the coating chamber, the first evaporation source can be heated in the coating chamber to form the first film layer. For example, the first evaporation source can be heated by the evaporation source placement component, or by an electron beam gun or a laser (the electron beam gun or the laser can be disposed in the coating chamber for example), the embodiments of the present disclosure are not limited thereto.

It should be noted that, before heating the first evaporation source to form the first film layer on the substrate, the coating chamber can be vacuumized, and the film forming process for example can refer to the relevant technology, and the redundant description is omitted here.

In the sub-step 4053, the sealing component between the first evaporation source chamber and the coating chamber are opened. For example, after forming the first film layer on the substrate, the sealing component between the first evaporation source chamber and the coating chamber can be opened so that the evaporation source placement component can be taken back in the subsequent steps.

In the step 406, the evaporation source placement component is moved into the first evaporation source chamber through the evaporation source moving component. For example, after the first evaporation source is heated in the coating chamber to form the first film layer, the evaporation source placement component can be moved into the first evaporation source chamber through the evaporation source moving component.

In the step 407, the sealing component between the first evaporation source chamber and the coating chamber is closed. For example, after moving the evaporation source placement component into the first evaporation source chamber, the sealing component between the first evaporation source chamber and the coating chamber can be closed so as to partition the first evaporation source chamber and the coating chamber.

After closing the sealing component, if the film coating process on the substrate has been finished, the coating chamber can be opened for taking the substrate out, and if it is necessary to form other film layers on the substrate, the subsequent steps can be executed, that is to say that the subsequent steps are optional steps.

In the step 408, the second evaporation source is disposed on the evaporation source placement component in the second evaporation source chamber. For example, the evaporation device can comprise at least two evaporation source chambers. In addition to the first evaporation source chamber, the evaporation device can further comprise a second evaporation source chamber, and the second evaporation source chamber can be any one of the at least two evaporation source chambers in addition to the first evaporation source chamber. If it is necessary to form another film layer on the substrate, a second evaporation source can be disposed on the evaporation source placement component in the second evaporation source chamber. For example, in the evaporation device illustrated by FIG. 2-4, a second evaporation source can be disposed on the evaporation source placement component 121b in the second evaporation source chamber 12b.

In the step 409, the second evaporation source is heated to form a second film layer. For example, after disposing a second evaporation source on the evaporation source placement component in the second evaporation source chamber, the second evaporation source can be heated to form a second film layer on the substrate, and the process of forming the second film layer on the substrate in the present step can refer to step 404 to step 406. Namely, the following operations can be conducted: moving the evaporation source placement component in the second evaporation source chamber into the coating chamber, closing the sealing component between the second evaporation source chamber and the coating chamber, and heating the second evaporation source to form the second film layer on the substrate, and the redundant description will be omitted here.

In the step 410, the sealing component between the second evaporation source chamber and the coating chamber is closed. For example, after forming a second film layer on the substrate, the sealing component between the second evaporation source chamber and the coating chamber can be closed. After that, the substrate which has been coated with films can be taken out.

It should be noted that, after forming a second film layer on the substrate, the first evaporation source in the first evaporation source chamber can be replaced with a new evaporation source at the same time, or a new evaporation source can be disposed on an evaporation source placement component in the third evaporation source chamber (a chamber in addition to the first evaporation source chamber and the second evaporation source chamber), so as to continue to coat another film. In this way, a plurality of evaporation sources can be continuously used to coat films, which can realize relatively high testing efficiency in testing the evaporation materials and can reduce the pollution by air on the evaporation source. Besides, for replacing the evaporation source in the evaporation method provided by an embodiment of the present disclosure, it is not necessary to wait for the evaporation source cooling, and it is not necessary to open the coating chamber, which prevents the substrate and evaporation sources contacting the external environment during film coating processes on the substrate, improves the quality and speed of forming film layers on the substrate, reduces the times of vacuumizing the coating chamber, and improves the working efficiency of the evaporation device as well.

It should be noted that, the evaporation method provided by an embodiment of the present disclosure can achieve the ability of alternately using the evaporation sources in the two evaporation source chambers to coat films on the substrate, improving the speed of coating films, and preventing the evaporation source contacting the external air, and can reduce the times of evaporation source maintenance by disposing at least two evaporation source chambers.

It should be noted that, the evaporation method provided by an embodiment of the present disclosure achieves the effect of accelerating the speed of coating films and reducing the waste of evaporation sources by closing the sealing component between the first evaporation source chamber and the coating chamber during coating a film on the substrate in the coating chamber.

To sum up, the evaporation method provided by an embodiment of the present disclosure can resolve the problem that the environment air may contact and contaminate an evaporation source when it is necessary to open the coating chamber for replacing a substrate in operation after an evaporation device in the related technology finishes a film coating process, and the evaporation method disposes at least one evaporation source chamber configured for placing the evaporation source and connects or disconnects the evaporation source chamber and a coating chamber through the sealing component disposed between the evaporation source chamber and the coating chamber, and achieves the effect of preventing the air contaminating the evaporation source when disconnecting the evaporation source chamber and the coating chamber by closing the sealing component after completion of film coating.

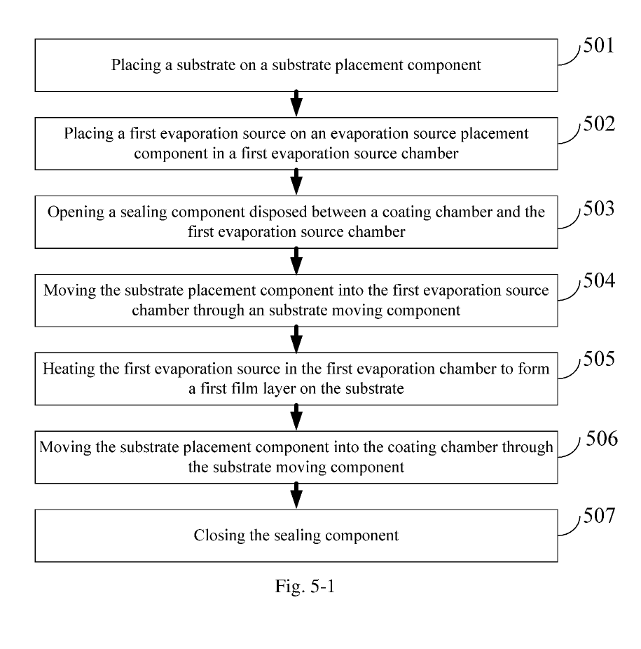

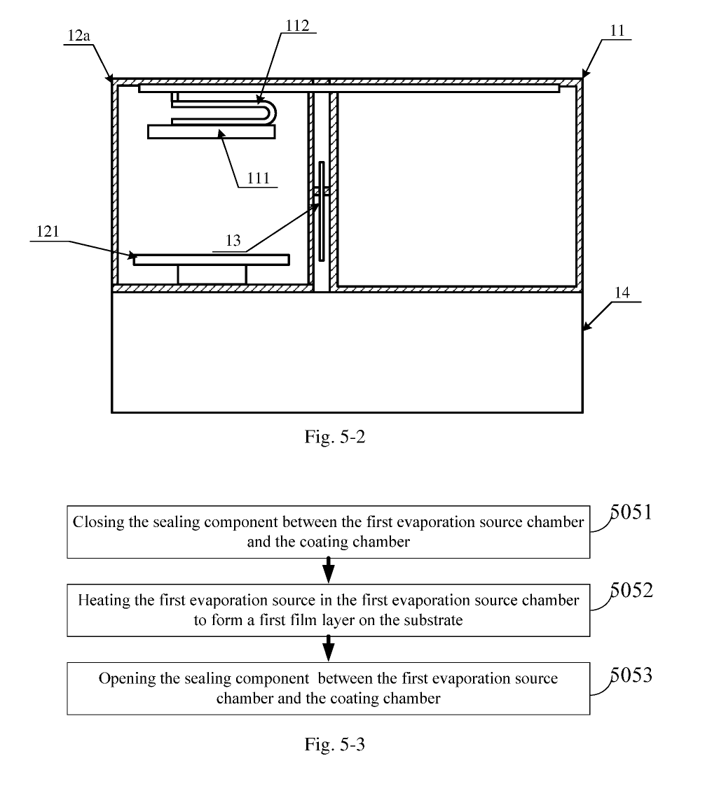

FIG. 5-1 is a flow diagram of another evaporation method for evaporation device provided by an embodiment of the present disclosure. The evaporation device can comprise: a coating chamber and at least one evaporation source chamber, the coating chamber is provided with a substrate placement component, the first evaporation source chamber is provided with an evaporation source placement component, the first evaporation source chamber can be any one of the at least one evaporation source chamber, the coating chamber and the first evaporation source chamber are provided with a sealing component therebetween, the coating chamber is further provided with a substrate moving component, and the method comprises the following operations:

Step 501, placing a substrate on the substrate placement component;

Step 502, placing a first evaporation source on the evaporation source placement component in the first evaporation source chamber;

Step 503, opening the sealing component between the coating chamber and the first evaporation source chamber;

Step 504, moving the substrate placement component into the first evaporation source chamber through the substrate moving component;

Step 505, heating the first evaporation source in the first evaporation source chamber to form a first film layer on the substrate;

Step 506, moving the substrate placement component into the coating chamber through the substrate moving component; and

Step 507, closing the sealing component.

In the step 501, a substrate can be disposed on the substrate placement component. For example, in the operation of the evaporation method provided by an embodiment of the present disclosure to conduct evaporation, the substrate can be disposed on the substrate placement component, for example the substrate is a work piece to be coated with a film, and the purpose of the evaporation is to form a film layer on the substrate. The substrate placement component can drive the substrate to rotate, so as to improve the evenness of the film layer formed on the substrate. For example, the substrate can be disposed on the substrate placement component by passing through a first gate.

In the step 502, a first evaporation source is disposed on the evaporation source placement component in the first evaporation source chamber. For example, in the embodiments, the first evaporation source can be disposed on the evaporation source placement component in the first evaporation source chamber, while the evaporation source moving component can be provided with a temperature measure element (for example, a thermoelectric couple), a cooling water pipe, a power line and a heating element (for example, a tungsten filament). The temperature measure element is configured to measure the temperature of the evaporation source, the cooling water pipe is configured to provide water flow to balance the temperature of the evaporation source, and the power line is configured to provide electrical energy to the heating element. The evaporation source moving component can allow the evaporation source to be maintained at a relatively constant temperature for evaporation through the temperature element, the cooling water pipe, the power line and the heating element. The first evaporation source can be disposed on the evaporation source placement component by opening a second gate disposed on the first evaporation source chamber. The first evaporation source can be one or several kinds of materials to form films. After the second gate to place the evaporation source is opened, it is necessary to close the second gate to partition the external environment and the first evaporation source chamber.

In the step 503, the sealing component between the coating chamber and the first evaporation source chamber is opened. For example, after the evaporation source and the substrate are placed, the sealing component between the coating chamber and the first evaporation source chamber can be opened.

It should be noted that, if the sealing component between the coating chamber and the first evaporation source chamber has been in an open state, the present step can be omitted.

In step 504, the substrate placement component is moved into the first evaporation source chamber through the substrate moving component. For example, in the embodiments, after the sealing component between the coating chamber and the first evaporation source chamber is opened, the substrate placement component can be moved into the first evaporation source chamber through the substrate moving component. Taking the evaporation device illustrated by FIG. 2-2 as an example, after moving the substrate placement component 111 into the first evaporation source chamber through the substrate moving component, the evaporation device can be illustrated by FIG. 5-2, and the drawing reference numbers in FIG. 5-2 are same as those in FIG. 2-2.

In the step 505, the first evaporation source is heated in the first evaporation source chamber to form a first film layer on the substrate. For example, in the embodiments, after moving the substrate placement component into the first evaporation source chamber, the first evaporation source can be heated in the first evaporation source chamber to form a first film layer.

As illustrated by FIG. 5-3, the step 505 can comprise the following three sub-steps:

Sub-step 5051, closing the sealing component between the first evaporation source chamber and the coating chamber;

Sub-step 5052, heating the first evaporation source in the first evaporation source chamber to form a first film layer on the substrate; and

Sub-step 5053, opening the sealing component between the first evaporation source chamber and the coating chamber.

Sub-step 5051, closing the sealing component between the first evaporation source chamber and the coating chamber. For example, after the substrate placement component is moved into the first evaporation source chamber, firstly, the sealing component between the first evaporation source chamber and the coating chamber can be closed. In this way, the problem can be avoided that evaporated or sublimated substance may escape into the coating chamber after the evaporation source is evaporated or sublimated, and the escape may reduce the forming speed of the thin film on the substrate and waste the evaporation source.

In the sub-step 5052, the first evaporation source is heated in the first evaporation source chamber to form a first film layer on the substrate. For example, in the embodiments, after closing the sealing component between the first evaporation source chamber and the coating chamber, the first evaporation source can be heated in the first evaporation source chamber to form the first film layer. For example, the first evaporation source can be heated by the evaporation source placement component, or by an electron beam gun or a laser (the electron beam gun or the laser can be disposed in the coating chamber for example), the embodiments of the present disclosure are not limited thereto. Besides, the specific film forming processes of the first film layer can refer to the relevant technologies, the embodiments of the present disclosure do not repeat herein.

In the sub-step 5053, the sealing component between the first evaporation source chamber and the coating chamber is opened. For example, after forming the first film layer on the substrate, the sealing component between the first evaporation source chamber and the coating chamber can be opened, so that the evaporation source placement component can be taken back in the subsequent steps.

In the step 506, the substrate placement component is moved into the coating chamber through the substrate moving component. For example, after the first evaporation source is heated in the first evaporation source chamber to form the first film layer, the substrate placement component can be moved into the coating chamber through the substrate moving component.

In the step 507, the sealing component is closed. For example, in the embodiments, after moving the substrate placement component into the coating chamber, the sealing component can be closed so as to partition the first evaporation source chamber and the coating chamber.

After the sealing component is closed, if the film coating on the substrate has been finished, the coating chamber can be opened to take the substrate out, and further if it is necessary to form other film layer on the substrate, the subsequent steps can be executed, the subsequent steps can refer to steps 408-410 in the embodiments illustrated by FIG. 4-1, which are not repeated here.

It should be noted that, the evaporation method provided by an embodiment of the present disclosure achieves the ability to coat a film in the first evaporation source chamber by disposing a substrate moving component and using the substrate moving component to drive the substrate placement component to move into the first evaporation source chamber.

To sum up, the evaporation method provided by an embodiment of the present disclosure can resolve the problem that the environment air may contact and contaminate an evaporation source when it is necessary to open the coating chamber for replacing a substrate in operation after an evaporation device in the related technology finishes a film coating process, and the evaporation method disposes at least one evaporation source chamber configured for placing the evaporation source and connects or disconnects the evaporation source chamber and a coating chamber through the sealing component disposed between the evaporation source chamber and the coating chamber, and achieves the effect of preventing the air contaminating the evaporation source when disconnecting the evaporation source chamber and the coating chamber by closing the sealing component after completion of film coating.

The foregoing are merely specific embodiments of the invention, but not limitative to the protection scope of the present disclosure. Therefore, the protection scope of the invention should be defined by the accompanying claims.

The present disclosure claims the benefits of Chinese patent application No. 201510666908.0, which was filed with the SIPO on Oct. 15, 2015 and is fully incorporated herein by reference as part of this application.

What is claimed is:

1. An evaporation device, comprising:
a coating chamber and a first evaporation source chamber, wherein the coating chamber is provided with a substrate placement component, and the substrate placement component is configured for placing a substrate, the first evaporation source chamber is provided with an evaporation source placement component, and the evaporation source placement component is configured for placing an evaporation source; and
a sealing component provided between the coating chamber and the first evaporation source chamber, wherein the sealing component is configured to connect the coating chamber and the first evaporation source chamber upon being opened and to disconnect the coating chamber and the first evaporation source chamber upon being closed.

2. The evaporation device according to claim 1, wherein the first evaporation source chamber is further provided with an evaporation source moving component,
the evaporation source moving component is connected with the evaporation source placement component and configured to drive the evaporation source placement component to move into the coating chamber upon the sealing component being opened.

3. The evaporation device according to claim 1, wherein the coating chamber is further provided with a substrate moving component,
the substrate moving component is connected with the substrate placement component, and configured to drive the substrate placement component to move into the first evaporation source chamber upon the sealing component being opened.

4. The evaporation device according to claim 1, further comprising a second evaporation source chamber, wherein the second evaporation source chamber is provided with a second evaporation source placement component, and the second evaporation source placement component is configured for placing the evaporation source or another evaporation source.

5. The evaporation device according to claim 4, further comprising a second sealing component provided between the coating chamber and the second evaporation source chamber,
wherein the second sealing component is configured to connect the coating chamber and the second evaporation source chamber upon being opened and to disconnect the coating chamber and the second evaporation source chamber upon being closed.

6. The evaporation device according to claim 5, wherein the second evaporation source chamber is further provided with a second evaporation source moving component, and
the second evaporation source moving component is connected with the second evaporation source placement component.

7. The evaporation device according to claim 1, wherein the coating chamber is provided with a first gate, the first gate is configured to disconnect or connect the coating chamber and the external environment.

8. The evaporation device according to claim 1, wherein the first evaporation source chamber is provided with a second gate, and the second gate is configured to disconnect or connect the first evaporation source chamber and the external environment.

9. The evaporation device according to claim 4, wherein the second evaporation source chamber is provided with a third gate, and the third gate is configured to disconnect or connect the second evaporation source chamber and the external environment.

10. An evaporation method for the evaporation device, wherein the evaporation device comprises a coating chamber and a first evaporation source chamber, the coating chamber is provided with a substrate placement component, the first evaporation source chamber is provided with an evaporation source placement component, and the coating chamber and the first evaporation source chamber are provided with a sealing component therebetween, and the method comprises:
placing a substrate on the substrate placement component;
placing a first evaporation source on the evaporation source placement component in the first evaporation source chamber;
opening the sealing component between the coating chamber and the first evaporation source chamber;
heating the first evaporation source to form a first film layer on the substrate; and
closing the sealing component.

11. The method according to claim 10, wherein the first evaporation source chamber is further provided with an evaporation source moving component.

12. The method according to claim 11, wherein heating of the first evaporation source to form the first film layer on the substrate comprises:
moving the evaporation source placement component into the coating chamber through the evaporation source moving component;
heating the first evaporation source in the coating chamber to form the first film layer on the substrate; and
moving the evaporation source placement component into the first evaporation source chamber through the evaporation source moving component.

13. The method according to claim 11, wherein heating of the first evaporation source in the coating chamber to form the first film layer on the substrate comprises:
closing the sealing component between the first evaporation source chamber and the coating chamber;
heating the first evaporation source in the coating chamber to form the first film layer on the substrate; and
opening the sealing component between the first evaporation source and the coating chamber.

14. The method according to claim 10, wherein the coating chamber is further provided with a substrate moving component.

15. The method according to claim 14, wherein heating of the first evaporation source to form the first film layer on the substrate comprises:
moving the substrate placement component to the first evaporation source chamber through the substrate moving component;
heating the first evaporation source in the first evaporation source chamber to form the first film layer on the substrate; and
moving the substrate placement component into the coating chamber through the substrate moving component.

16. The method according to claim 14, wherein heating of the first evaporation source in the first evaporation source chamber to form the first film layer on the substrate comprises:
closing the sealing component between the first evaporation source chamber and the coating chamber;
heating the first evaporation source in the first evaporation source chamber to form the first film layer on the substrate; and
opening the sealing component between the first evaporation source chamber and the coating chamber.

17. The method according to claim 10, wherein the evaporation device further comprises a second evaporation source chamber, after closing the sealing component, the method further comprises:
placing a second evaporation source on the evaporation source placement component in the second evaporation source chamber;
heating the second evaporation source to form a second film layer on the substrate; and
closing the sealing component between the second evaporation source chamber and the coating chamber.
